(19) United States
(12) Patent Application Publication
(10) Pub. No.: US 2004/0262685 A1
(43) Pub. Date: Dec. 30, 2004

(54) Thin film lateral soi power device

(76) Inventor: Rene Paul Zingg, Nijmegen (NL)

Correspondence Address: PHILIPS ELECTRONICS NORTH AMERICA CORPORATION, INTELLECTUAL PROPERTY & STANDARDS, 1109 MCKAY DRIVE, M/S-41SJ, SAN JOSE, CA, 95131, US

(21) Appl. No.: 10/494,108

(22) PCT Filed: Oct. 24, 2002
(86) PCT No.: PCT/IB02/04458

(30) Foreign Application Priority Data
Nov. 1, 2001 (EP) 01204205.7

(51) Int. Cl. H01L 27/01

(52) U.S. Cl. 257/347

(57) ABSTRACT

A thin film lateral SOI power device comprises a substrate and a buried oxide layer (4) on the substrate; a silicon layer (6) on the buried oxide layer, the silicon layer having a laterally extending drift region; a dielectric layer on the silicon layer (6), the dielectric layer having a gate dielectric layer (18), a field dielectric layer (20) and a drift dielectric layer (22) having thickness larger than the thickness of the field dielectric layer (24) and a dielectric layer transition region (24) between the field dielectric layer and the drift dielectric layer; a gate (26) located above a channel region (27) in the first silicon layer thickness region (10) and extending as a field plate (28, 36,44) from the channel region (27) across at least the field dielectric layer (20); a drain (30) laterally spaced to the third thickness region (12) of the silicon layer (6); and a source (32) laterally separated from the gate; wherein in a drift region extending in the silicon layer (6) from the channel region (27) towards the drain (30), the doping dose (impurities per unit of area) is scaled such that a steady increase in concentration (impurities per unit of volume) produces a constant longitudinal electric field irrespective of thickness transitions in the silicon layer (6) and/or the dielectric layer (18,20,22) and/or the field plate (28). The method of fabricating the above thin film lateral SOI power device comprises scaling the doping dose in the drift region of the silicon layer such that a steady increase of the longitudinal doping density results in a constant electric field in the drift region of the silicon layer irrespective to thickness transitions in the silicon layer and/or the top oxide layer and/or the field plate. The driving in of the dopant in the drift region of the silicon layer is carried out after forming the top oxide layer.

The invention relates to a thin film lateral SOI power device.

Lateral SOI power devices show degraded high-side performance due to depletion from handle wafer. The degradation has been minimized by going to step- and stair-thin-film SOI LDMOS (lateral double diffused metal oxide semiconductor) device as shown in WO 00/31776, which in fact maximizes the silicon film thickness and available doping therein. In this device, a so called step- and stair SOCOS, the silicon film thickness and the proximity of the field-plate is increased near the drain, as compared to the former state of art. There is still the disadvantage with this known SOCOS device that the volume doping density experiences a sudden increase at the transition from field oxide to drift oxide due to thickness variation in the silicon layer and the top oxide respectively and to dopant pile-up during the oxidation of the drift oxide. This increase in doping density results in a local increase of the longitudinal electric field according to Gauss' theorem, which in turn increases carrier multiplication by impact ionization.

It is an objective of the invention to provide a lateral thin film SOI power device and a method of making the same where the slope of the doping concentration is steady, thereby producing a constant longitudinal electric field along the drift region of the device.

For achieving this objective, the thin film lateral SOI power device according to the invention comprises a substrate and a buried oxide layer on the substrate; a silicon layer on the buried oxide layer, the silicon layer having a laterally extending drift region comprising at least a first thickness region and a second thickness region having a thickness smaller than the first thickness region and a transition between the first thickness region and the second thickness region; a dielectric layer on the first and second thickness regions of the silicon layer, the dielectric layer having a gate dielectric layer, a field dielectric layer and a drift dielectric layer having thickness larger than the thickness of the field dielectric layer and a dielectric layer transition region between the field dielectric layer and the drift dielectric layer; a gate located above a channel region in the first silicon layer thickness region and extending as a field plate from the channel region across at least the field dielectric layer; a drain laterally spaced to the third thickness region of the silicon layer; and a source laterally separated from the gate; wherein in a drift region extending in the silicon layer from the channel region towards the drain, the doping dose (impurities per unit of area) is scaled such that a steady increase in concentration (impurities per unit of volume) produces a constant longitudinal electric field irrespective of thickness transitions in the silicon layer and/or the dielectric layer and/or the field plate.

The thin film lateral SOI power device comprises a substrate and a buried oxide layer on the substrate, a silicon layer on the buried oxide layer, a dielectric layer (preferably grown oxide) on the silicon layer, a gate or field-plate located on top of this dielectric, a further dielectric, a metal layer and a passivation layer (not shown). The silicon layer is sequentially reduced towards the drain, and the dielectric is increased from gate to field to drift oxide, whereas the drain contact just as the source and channel are situated in thick silicon film with minimum dielectric coverage by the gate-oxide. The uniform slope of doping concentration and the constant longitudinal field in the drift region of the silicon layer is important to minimize carrier generation by impact ionization. The scaling of implantation dose may be provided at any thickness transition and/or any transition in the field plate. The doping volume concentration in the drift region of the silicon layer, i.e. in the silicon layer below the field oxide and the drift oxide, is almost smooth, whereas the doping dose is scaled as stated above. Also the figure-of-merit of the onresistance (Ron) versus Breakdown Voltage between drain and source (BVds) is improved.

According to an advantageous embodiment, the invention provides a thin film lateral SOI power device wherein a slope a of the doping dose in the first thickness region of the silicon layer is increased to a level resulting in a steady increase of the longitudinal field in the drift region of the silicon layer.

According to an advantageous embodiment, the invention provides a thin film lateral SOI power device wherein the slope a of the doping dose curve in said first thickness region of the silicon layer below the field oxide is doubled as compared to a basic slope β of a basic doping dose curve in the adjacent portion of the drift region of the silicon layer below the drift oxide. S the slope of the doping dose at the beginning of the drift region with thick silicon and thin dielectric is increased by a factor of two, accelerating voltage build-up and reducing resistivity. Furthermore, the increased doping density under field dielectric layer mainly compensates any disturbances of the lateral field due to the thickness transition in the dielectric layer from the field dielectric layer to the drift dielectric layer and also due to the fact that the field plate connected to the gate ends at that location. The increased doping density under field oxide also serves to compensate for the effect with SOCOS devices that the volume doping density experiences a sudden increase at the transition from field dielectric layer to drift dielectric layer. By means of this compensation, the doping density can be increased close to the impact-ionization limit also in this part of the device.

According to an advantageous embodiment, the invention provides a thin film lateral SOI power device wherein the dielectric layers are oxide layers preferably made by LOCOS.

According to an advantageous embodiment, the invention provides a thin film lateral SOI power device having a further field plate extending beyond the first field plate and comprising a first metal layer and a second metal layer, the second metal layer being isolated from the first metal by an additional dielectric layer, the device further having a third thickness region in the silicon layer which has a smaller thickness than the second thickness region of the silicon layer, wherein slope of the doping dose in the third thickness region of the silicon layer is reduced with respect to the slope of doping dose in the second thickness region of the silicon layer to a level resulting in a steady increase of the longitudinal field in the drift region of the silicon layer. This further removed field-plate could preferably be above a further thinned SOI layer, as would result by combining the oxide growth of field- and drift-oxide, yielding also thicker thermal oxide. The slope of the doping dose in this region is reduced compared to the slope under the first metal field-plate to a level resulting in a steady increase of the longitudinal field in the drift region of the silicon layer.

For achieving the above objective, the invention also provides a method for fabricating a thin film lateral SOI power device wherein the doping dose in the drift region of the silicon layer is scaled such that a steady increase of the longitudinal doping density results in a constant electric field in the drift region of the silicon layer irrespective to thickness transitions in the silicon layer and/or the top oxide layer and/or the field plate, and wherein the driving in (annealing or smoothening) of the dopant in the drift region of the silicon layer is carried out after forming the top oxide layer in order to minimize pile-up artifacts due to oxidations.

According to an advantageous embodiment, the invention also provides a method for fabricating a thin film lateral SOI power device wherein the different diffusion speeds and segregation coefficients of the dopant in the silicon and the silicon oxide is taken into account when determining the implantation dose.

According to an advantageous embodiment, the invention also provides a method for fabricating a thin film lateral SOI power device wherein the scaling of the doping density is done by implanting the dopant through openings in an implantation mask the size and/or number of which openings being varied according to the required dose.

A most preferred embodiment of the invention is summarized as follows. A thin film lateral SOI power device comprises a buried oxide layer (BOx) on a substrate and a silicon layer on the buried oxide layer. The silicon layer contains a laterally extending drift region comprising a first thickness region, a second thickness region having a thickness smaller than the first thickness region and a third thickness region having a thickness smaller than the second thickness region. This silicon layer is covered by a suitable dielectric, in may cases preferably (locally) grown oxide. This dielectric will be called gate-oxide in the gate region, field-oxide and drift-oxide with sequentially increasing thickness. A gate electrode extends as a first field-plate onto the field-oxide and may preferably consist of polysilicon. A second field-plate is electrically isolated from and by dielectric and could be connected to source, gate or another suitable potential of the circuit. The doping density in the drift region of the silicon layer is scaled such that a steady increase of electric potential and a constant longitudinal field in the drift region of the silicon layer is provided irrespective to thickness transitions in the silicon layer and/or the top oxide layer and/or the field plate. When fabricating the device, the driving in of the dopant in the drift region of the silicon layer is carried out after forming the top oxide layer.

Embodiments of the invention are now described with reference to the drawings, in which:

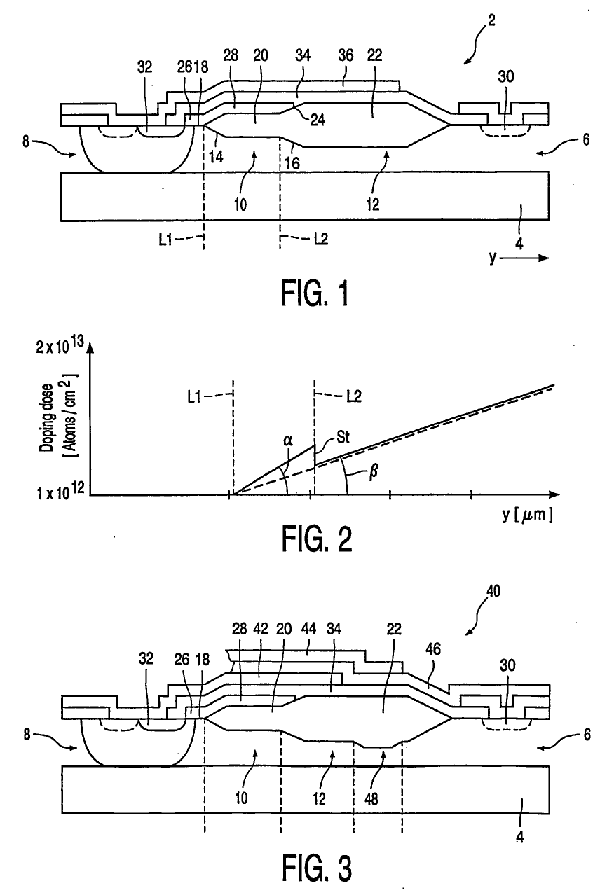

FIG. 1 is schematic cross section through a device according to an embodiment of the invention;

FIG. 2 shows a profile of a doping dose of 1×10¹² to 2×10¹³ cm⁻² along the distance y in the device of FIG. 1 compared to the state of the art;

FIG. 3 is schematic cross section through another device according to an embodiment of the invention; and

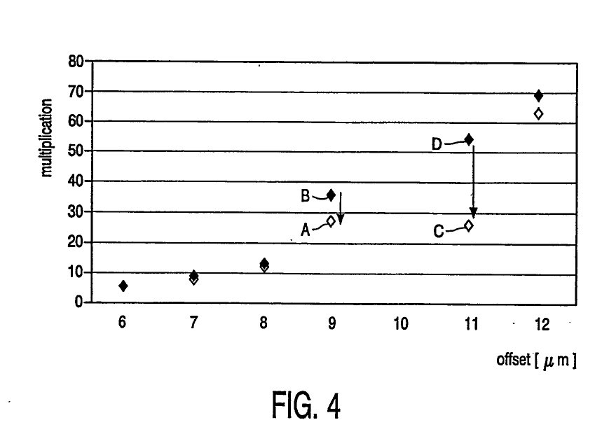

FIG. 4 is graph showing carrier multiplication by impact ionization in several devices versus offset.

FIG. 1 shows a thin film lateral SOI power device of an embodiment of the invention. The device 2 comprises a buried oxide layer (BOx) 4 on a substrate (not shown) and a silicon layer 6 on the buried oxide layer 4, the silicon layer having a laterally extending drift region comprising a first thickness region 8, a second thickness region 10 having a thickness smaller than the first thickness region 8 and a third thickness region 12 having a thickness smaller than the second thickness region 10. A first transition 14 is located between the first thickness region 8 and the second thickness region 10 and a second transition 16 is located between the second thickness region 10 and the third thickness region 12.

A top oxide layer (TOx) is provided on the second and third thickness regions of the silicon layer 6, the top oxide layer having a field oxide region 20 and a drift oxide region 22 having thickness larger than the thickness of the a field oxide region 20. An oxide layer transition region 24 is located between the field oxide region 20 and the drift oxide region 22. A gate region 26 located above the first silicon layer thickness region 8 and extends as a field plate 28 above the field oxide region 20. A drain region 30 is laterally spaced from the third thickness region 12 of the silicon layer 6. A source region 32 is laterally separated from the gate region 26.

The gate region 26 comprises a polysilicon layer and is covered by a further oxide layer 34. On top of the further oxide layer 34, a further metal field plate 36 is provided which extends from the source region 32 across the further oxide layer 34 to almost an end of the drift oxide region 22. In such a SOI device called step and stair SOI device, the doping density in the drift region of the silicon layer is scaled such that a steady increase in concentration (impurities per unit of volume) produces a constant longitudinal electric field irrespective of thickness transitions in the silicon layer and/or the top oxide layer and/or the field plate.

A device of the invention as shown in FIG. 1 may typically have a drift region of a length of about 50 μm, a thickness of the first thickness region 10 of the silicon layer tsoi1=1 μm, a thickness of the second thickness region 12 of the silicon layer tsoi2=560 nm. A thickness of the field oxide TOx1 would be 0,775 μm, a thickness of the drift oxide TOx2=2.3 μm and a thickness of the buried oxide BOx=3 μm. Tuning the thickness of the buried oxide and the silicon layer in such a way and by merging the end of the field plate into the transition region results in a reduction of the depth of the potential trough in the region of the silicon layer at the transition from the field oxide to the drift oxide. The drift region in such a device has a basic slope a of doping density across the length of the drift region 50 μm in this example resulting in a maximum doping dose of about 1.1×10¹³ cm⁻² on the end of the drift region next to the drain.

In such a device the length of the field oxide is about 10 μm, and the scaling of the doping density should then have a profile as shown in FIG. 2 where the slope a of the doping dose in the first thickness region of the silicon layer is increased to a level resulting in a steady increase of the electric potential in the drift region of the silicon layer. In particular, the slope α of the doping dose in said first thickness region of the silicon layer is doubled as compared to the slope β of the doping dose in the adjacent portion of the drift region of the silicon layer below the drift oxide, resulting in lower resistivity in on-state and faster voltage build-up in off-state.

In the drift region of the silicon layer below the drift oxide, the starting value of the doping dose in the silicon layer below the transition from the field oxide to the drift oxide is selected to be the basic doping dose curve which represents the doping in devices of the state of art. Therefore, a step St of the doping dose is produced below the transition of the field oxide to the drift oxide which smoothens the lateral field in this area. It is to be noted that the doping profile shown in FIG. 2 comes on top of the doping of the silicon layer 6 as a whole. It is important to note that the discontinuity in the doping dose of FIG. 3 at 10 μm (but depending on the chosen geometry and doping parameters possibly between 5 and 15 μm) is greatly reduced in the volume doping concentration.

Another embodiment of the thin film lateral SOI device 40 of the invention is shown in FIG. 3 in which the same reference numerals are used for the same parts as in FIG. 1. In the device 40, the further field plate is embodied by a first metal layer 42 and a second metal layer 44, the second metal layer being isolated from the first metal layer 42, by a dielectric layer 46. The second metal layer 44 may be connected to the source, to the gate or to a separate potential.

The schematic cross-section of the device 40 has three different silicon thickness regions, namely a region 10 below the field oxide 20 a region 12 below a part of the drift oxide 22 and a region 48 below a region of the drift oxide below the second metal field plate 44. The thickness of the top oxide also varies from the field oxide under the polysilicon gate 26/28 to an intermediate thickness in the drift oxide below the first metal portion 42 of the further field plate to a larger thickness of the drift oxide below the second portion 44 of the further field plate plus deposited oxide under the second portion 44 of the further field plate.

In a typical device of FIG. 3, the thickness of the silicon layer in the region 10 is tsoi1=1 μm, the thickness of the silicon layer in the region 12 is tsoi2=560 nm, the thickness of the silicon layer in the region 48 is tsoi3=425 nm, the thickness of the field oxide 20 is TOx1=0,775 μm, the thickness of a first portion of the drift oxide 22 is TOx2=2.3 μm, and the thickness of a second portion of the drift oxide is TOx3=3.1 μm, and the thickness of the buried oxide is BOx=3 μm. In such a device, the slopes of the doping dose would be selected in the region 10 to be equal to the slope a in FIG. 2, in the region 12 to be slightly higher than β in FIG. 2, and in the region 48 to be about equal to β in FIG. 2 in order to achieve a steady increase of the longitudinal potential in the drift region of the silicon layer.

The formula determining the doping concentration (i.e. the number of impurities introduced per unit volume) depends on SOI film thickness, buried oxide, top oxide thickness, and distance to origin of slope x as follows:

$$\frac{{TOx}^{2} {ϵ}_{si} + {BOx}^{2} {ϵ}_{si} + TOx * {t}_{SOI} {ϵ}_{ox} + BOx * {t}_{SOI} {ϵ}_{ox} + 3 TOx * BOx * {ϵ}_{si}}{2 {( ( TOx + BOx ) * \frac{{ϵ}_{si}}{{t}_{SOI}} + {ϵ}_{ox} )}^{2}} * kx + \frac{{TOx}^{2} BOx * {ϵ}_{si}^{2} + TOx * {BOx}^{2} {ϵ}_{si}^{2}}{{t}_{SOI} {{ϵ}_{ox} ( ( TOx + BOx ) * \frac{{ϵ}_{si}}{{t}_{SOI}} + {ϵ}_{ox} )}^{2}} * kx + \frac{{t}_{soi}^{2} {ϵ}_{ox}^{2}}{8 {{ϵ}_{si} ( ( TOx + BOx ) * \frac{{ϵ}_{si}}{{t}_{SOI}} + {ϵ}_{ox} )}^{2}} * kx$$

Where:

k is a factor determining the slope of doping, and therefore the lateral electric field,

TOx is the thickness of all dielectric layers between SOI film and field-plate,

BOx is the thickness of the buried oxide,

tsoi is the thickness of the silicon layer,

εox is the dielectric constant of the top dielectric, and

εsi is the dielectric constant of the silicon layer.

From this formula, a constantly rising volume concentration with constant slope results in a device as shown in FIGS. 1 and 3. The necessary dose to be implanted per unit area results from multiplying the volume concentration with the SOI thickness at this place.

FIG. 4 shows carrier multiplication by impact ionization in several devices versus offset, which is the distance in microns between the starting point of the field oxide and the transition from field oxide to the drift oxide. FIGS. 2 and 3 show for example an offset of 10 μm, indicated by dashed lines L1 and L2. FIG. 4 shows that the method for fabricating a thin film lateral SOI power device wherein the driving in of the dopant in the drift region of the silicon layer is carried out after forming the top oxide layer produces better results, i.e. less multiplication. The doping is done, as is known in the art by implanting the required dose into the silicon layer and thereafter driving in the dopant for example by thermal treatment.

The devices A and B have an offset of 9 μm. Multiplication is reduced in device A which was made by fabricating the top oxide layer first and then driving in the dopant as compared to the device B which was made by driving in the dopant first and then fabricating the top oxide layer. The reduction of the multiplication effect is a direct result of reduced lateral fields in the device caused by the scaling of the doping density. The devices C and D have an offset of 11 μm. Multiplication is reduced in device C which was made by fabricating the top oxide layer first and then driving in the dopant as compared to the device D which was made by driving in the dopant first and then fabricating the top oxide layer. The reduction of the multiplication effect was almost 50% in this case. At offsets of 6 to 8 μm, multiplication did not take place to a substantial amount. However, it is to be noted that lager offset are preferred e.g. to reduce high-side degradation by pinching from the handle wafer.

New characteristics and advantages of the invention covered by this document have been set forth in the foregoing description. It will be understood, however, that this disclosure is, in many respects, only illustrative. Changes may be made in details, particularly in matters of shape, size, and arrangement of parts, without exceeding the scope of the invention. The scope of the invention is, of course, defined in the language in which the appended claims are expressed.

1. A thin film lateral SOI power device comprising:
a substrate and a buried oxide layer (4) on the substrate;
a silicon layer (6) on the buried oxide layer, the silicon layer having a laterally extending drift region comprising at least a first thickness region (18) and a second thickness region (12) having a thickness smaller than the first thickness region (12) and a transition between the first thickness region (10) and the second thickness region (12);
a dielectric layer on the first and second thickness regions (10, 12) of the silicon layer (6), the dielectric layer having a gate dielectric layer (18), a field dielectric layer (20) and a drift dielectric layer (22) having thickness larger than the thickness of the field dielectric layer (24) and a dielectric layer transition region (24) between the field dielectric layer and the drift dielectric layer;
a gate (26) located above a channel region (27) in the first silicon layer thickness region (10) and extending as a field plate (28, 36,44) from the channel region (27) across at least the field dielectric layer (20);
a drain (30) laterally spaced to the third thickness region (12) of the silicon layer (6); and
a source (32) laterally separated from the gate; wherein
in a drift region extending in the silicon layer (6) from the channel region (27) towards the drain (30), the doping dose (impurities per unit of area) is scaled such that a steady increase in concentration (impurities per unit of volume) produces a constant longitudinal electric field irrespective of thickness transitions in the silicon layer (6) and/or the dielectric layer (18,20,22) and/or the field plate (28).

2. The thin film lateral SOI power device of claim 1, wherein a slope a of the doping dose in the first thickness region of the silicon layer is increased to a level resulting in a steady increase of the longitudinal field in the drift region of the silicon layer.

3. The thin film lateral SOI power device of claim 2, wherein the slope a of the doping dose curve in said first thickness region of the silicon layer below the field oxide is doubled as compared to a basic slope β of a basic doping dose curve in the adjacent portion of the drift region of the silicon layer blow the drift oxide.

4. The thin film lateral SOI power device of claim 3, wherein a starting value of the doping dose in the silicon layer below the transition from the field oxide to the drift oxide is selected to result in the same doping density as the adjacent silicon layer.

5. The thin film lateral SOI power device of claim 1, the device having a further field plate extending beyond the first field plate and comprising a first metal layer and a second metal layer, the second metal layer being isolated from the first metal by an additional dielectric layer, the device further having a third thickness region in the silicon layer which has a smaller thickness than the second thickness region of the silicon layer, wherein slope of the doping dose in the third thickness region of the silicon layer is reduced with respect to the slope of doping dose in the second thickness region of the silicon layer to a level resulting in a steady increase of the longitudinal field in the drift region of the silicon layer.

6. The thin film lateral SOI power device of claim 1, wherein the dielectric layers are oxide layers preferably made by LOCOS.

7. A method of fabricating a thin film lateral SOI power device of claim 1, wherein the doping density in the drift region of the silicon layer is scaled such that a steady increase of the longitudinal doping density results in a constant electric field in the drift region of the silicon layer irrespective to thickness transitions in the silicon layer and/or the top oxide layer and/or the field plate, and wherein the driving in of the dopant in the drift region of the silicon layer is carried out after forming the top oxide layer.

8. The method of claim 6, wherein the different diffusion speeds and segregation coefficients of the dopant in the silicon and the silicon oxide is taken into account when determining the implantation dose.

9. The method of claim 6, wherein the scaling of the doping density is done by implanting the dopant into the silicon layer through openings in an implantation mask the size and/or number of which openings being varied according to the required dose.

10. The thin film lateral SOI power device of claim 2, wherein the dielectric layers are oxide layers preferably made by LOCOS.

11. The thin film lateral SOI power device of claim 3, wherein the dielectric layers are oxide layers preferably made by LOCOS.

12. The thin film lateral SOI power device of claim 4, wherein the dielectric layers are oxide layers preferably made by LOCOS.

13. The thin film lateral SOI power device of claim 5, wherein the dielectric layers are oxide layers preferably made by LOCOS.
